(19) United States
(12) Patent Application Publication
(10) Pub. No.: US 2023/0042407 A1
(43) Pub. Date: Feb. 9, 2023

(54) METHOD OF MANUFACTURING SEMICONDUCTOR DEVICES AND CORRESPONDING SEMICONDUCTOR DEVICE METHOD OF MANUFACTURING SEMICONDUCTOR DEVICES AND CORRESPONDING SEMICONDUCTOR DEVICE

(71) Applicant: STMicroelectronics S.r.l., Agrate Brianza (MB) (IT)

(72) Inventors: Paolo CASATI, Sesto San Giovanni (IT); Federico FREGO, San Donato Milanese (IT)

(73) Assignee: STMicroelectronics S.r.l., Agrate Brianza (MB) (IT)

(21) Appl. No.: 17/878,676

(22) Filed: Aug. 1, 2022

(30) Foreign Application Priority Data
Aug. 4, 2021 (IT) 102021000021122

(51) Int. Cl. H01L 21/48; H01L 23/495

(52) U.S. Cl. CPC H01L 21/4842; H01L 23/49565; H01L 21/561

(57) ABSTRACT

Semiconductor devices are arranged in a chain extending in a longitudinal direction have mutually facing end sides transverse the longitudinal direction and are coupled via tie bars located at the mutually facing end sides. The tie bars are provided with anchoring tips penetrating into an insulating package at mutually facing end sides of the devices. The tie bars can be deformed to extract the anchoring tips from the insulating package at the mutually facing end sides of the devices. Individual singulated devices are thus produced in response to the anchoring tips being extracted from the mutually facing end sides of the devices.

### PRIORITY CLAIM

This application claims the priority benefit of Italian Application for Patent No. 102021000021122, filed on Aug. 4, 2021, the content of which is hereby incorporated by reference in its entirety to the maximum extent allowable by law.

### TECHNICAL FIELD

The description relates to semiconductor devices.

One or more embodiments can be applied to semiconductor power devices for the automotive sector, for instance.

### BACKGROUND

A well-controlled creepage distance is a desirable feature in high-voltage semiconductor device packages. The creepage distance denotes the shortest path between two conductive materials measured over the surface of an isolator arranged in between. An adequate creepage distance facilitates achieving isolation between two materials at different voltage and “pollution” levels. Specifications such as IEC CEI 60664-1 apply in that area.

An increased creepage distance in a semiconductor device package is advantageous in high-voltage applications: for instance, a small outline (SO) narrow package option (150 mils body) can be used in the place of a SO wide option (300 mils body) for a same application.

Package singulation is the final step in various manufacturing processes of semiconductor devices where plural semiconductor devices are manufactured simultaneously starting from a same leadframe and individual packages are finally separated from the leadframe with a cutting (shear) operation that severs sacrificial tie bars between the packages.

During package singulation, such tie bars tend to crack the molding compound around them. Also, remainders of the tie bars left exposed at the package surface have a negative effect on the creepage distance.

There is accordingly a need in the art to contribute to overcoming the drawbacks outlined in the foregoing.

### SUMMARY

One or more embodiments relate to a method.

One or more embodiments relate to a corresponding semiconductor device.

One of more embodiments provide a semiconductor device package that can be regarded as a “tie bar-less” package involving a slight redesign of leadframe without appreciable changes in the assembly flow.

One or more embodiments may involve using a specific tool to extract from the device packages those parts of the leadframe that are used to keep the semiconductor packages connected in a chain until the final singulation step (which step can be performed when the leads are already separated from the leadframe and formed).

One or more embodiments facilitate achieving a desired isolation (creepage distance) between two conductive materials, even in adverse environmental conditions such as high humidity and high pollution.

One or more embodiments facilitate reducing area consumption and achieving cost savings.

Semiconductor devices produced according to embodiments of the present description are exempt from package resin damage as possibly caused by dummy tie bars in conventional solutions.

Improved creepage distance can be likewise achieved by avoiding remainders of dummy tie bars left exposed at the package surface.

### BRIEF DESCRIPTION OF THE DRAWINGS

One or more embodiments will now be described, by way of example only, with reference to the annexed figures, wherein:

FIGS. 1A to 1D are exemplary of steps in conventional singulation in manufacturing semiconductor devices;

FIGS. 2A to 2E are further exemplary of steps in conventional singulation of semiconductor device packages, with FIG. 2E being a side view along line E-E′ in FIG. 2D;

FIGS. 3A to 3D are exemplary of steps in embodiments of the present description; FIG. 3C is a cross-sectional view along line C-C′ in FIG. 3B and FIG. 3D is a view of the portion of FIG. 3B indicated by arrow D reproduced on an enlarged scale; and

FIGS. 4A to 4D are exemplary of steps in embodiments of the present description; FIG. 4C is a cross-sectional view along line C″-C′″ in FIG. 4B and FIG. 4D is a view of the portion of FIG. 4B indicated by arrow D′ reproduced on an enlarged scale.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description, various specific details are illustrated in order to provide an in-depth understanding of various examples of embodiments according to the description. The embodiments may be obtained without one or more of the specific details, or with other methods, components, materials, etc. In other cases, known structures, materials, or operations are not illustrated or described in detail so that various aspects of the embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment”, “in one embodiment”, or the like, that may be present in various points of the present description do not necessarily refer exactly to one and the same embodiment. Furthermore, particular configurations, structures, or characteristics may be combined in any adequate way in one or more embodiments.

The headings/references used herein are provided merely for convenience and hence do not define the extent of protection or the scope of the embodiments.

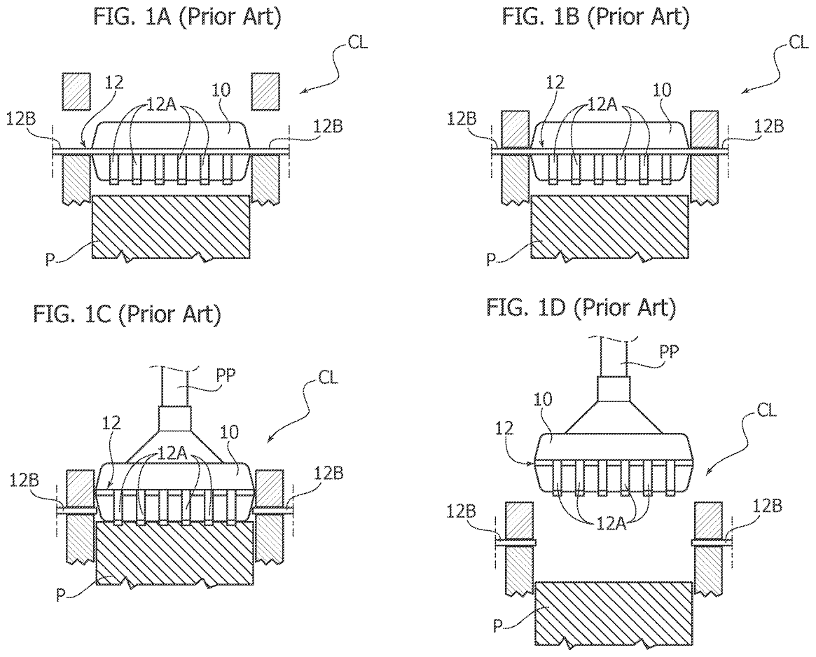

FIGS. 1A to 1D are exemplary of singulation in a conventional method of manufacturing semiconductor devices (of a variety of possible types).

As illustrated in FIGS. 1A to 1D, plural semiconductor devices 10 are manufactured simultaneously, with the devices 10 sharing a common leadframe strip 12 and being thus connected in a chain.

The designation “leadframe” (or “lead frame”) is currently used (see, for instance the USPC Consolidated Glossary of the United States Patent and Trademark Office) to indicate a metal frame that provides support for an integrated circuit chip or die (these terms are used herein as synonyms) as well as electrical leads to interconnect the integrated circuit in the die or chip to other electrical components or contacts.

Leadframes are conventionally created using technologies such as a photo-etching technology. With this technology, metal (e.g., copper) material in the form of a foil or tape is etched on the top and bottom sides to create various pads and leads.

As illustrated, the leadframe strip 12 includes leads 12A intended to provide connection pins for the individual devices 10 as well as so-called tie-bars 12B that connect adjacent semiconductor devices 10 in the chain.

Singulation, as illustrated in FIGS. 1A to 1D, is intended to release the individual devices 10 from the tie bars 12B, so that individual singulated devices 10 are obtained as desired.

More in detail, FIG. 1A is exemplary of the leadframe strip 12 with the device units 10 formed thereon being indexed into a separation tool. As illustrated, the separation tool is essentially comprised of a clamp structure CL and a punch P.

FIG. 1B is exemplary of the clamping structure CL being actuated to clamp the leadframe strip 12 at the tie bars 12B.

FIG. 1C is exemplary of the punch P (assumed to operate from the bottom or back surface of the device packages 10) moving upwards and pushing the device package 10 likewise upwards. As a result of punch movement, the tie bars 12B are cut at the periphery of the (plastic) package of the device 10. The device is thus released from the tie bars 12B and can be picked by a pick & place tool PP. This tool may comprise vacuum cups (suckers) that come into contact with the package body (at the front or top surface thereof, for instance). As a result, once released (separated) from the tie bars 12B, the individual devices 10 can be picked-up by the tool PP and moved to another processing station (deposited in a tray, boat, tape, or reel, for instance). The severing action of the tie bars 12B produced by the punch P as illustrated by the sequence of FIGS. 1B and 1C may undesirably result in cracks formed in the (plastic or resin) package of the device 10 at those locations where the tie bars 12B are cut.

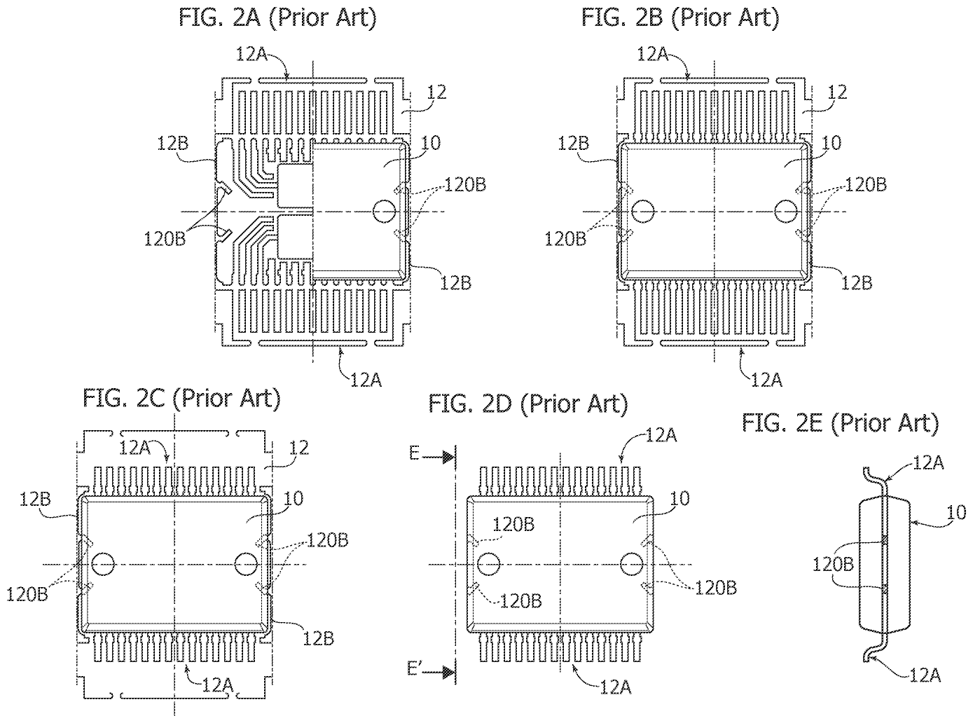

In FIGS. 2A to 2E parts or elements like parts or elements already discussed in connection with FIGS. 1A to 1D are indicated with like reference symbols, and a corresponding description will not be repeated for brevity.

The sequence of FIGS. 2A to 2E is illustrative of the fact that a conventional sequence of steps as illustrated in FIGS. 1A to 1D (with the tie bars 12B severed by the action of the punch P) results in end portions 120B of the tie bars 12B remaining in the semiconductor device packages at the (transversal) sides of the individual devices 10 where the tie bars 12B were provided.

As highlighted in FIGS. 2D and 2E, these end portions 120B remaining in the package of the final individual device 10 have a negative effect on creepage distance: in fact, these remaining end portions 120B (of an electrically conductive material such as copper, for instance) are left exposed at the surface of the device package.

FIGS. 1A to 1D and 2A to 2E are thus exemplary of a process of producing a plurality of semiconductor devices 10 coupled in a chain extending in a longitudinal direction (horizontal in FIGS. 2A to 2D). Neighboring devices 10 in the chain have mutually facing end sides (vertical in FIGS. 2A to 2D) transverse that longitudinal direction and are coupled via tie bars 12B located at the mutually facing transverse end sides.

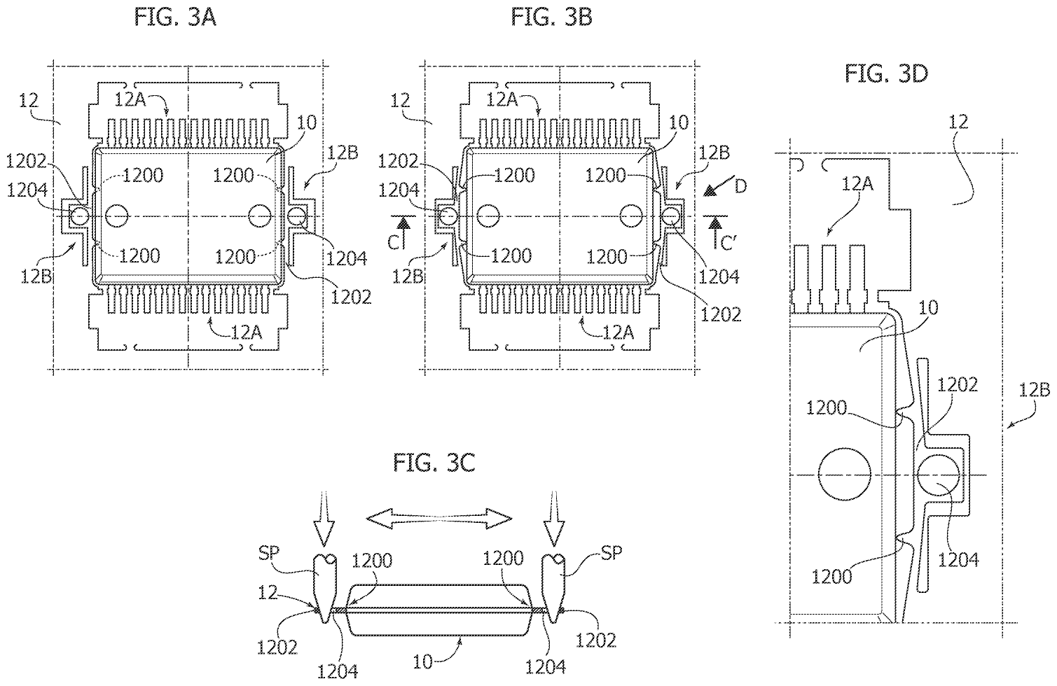

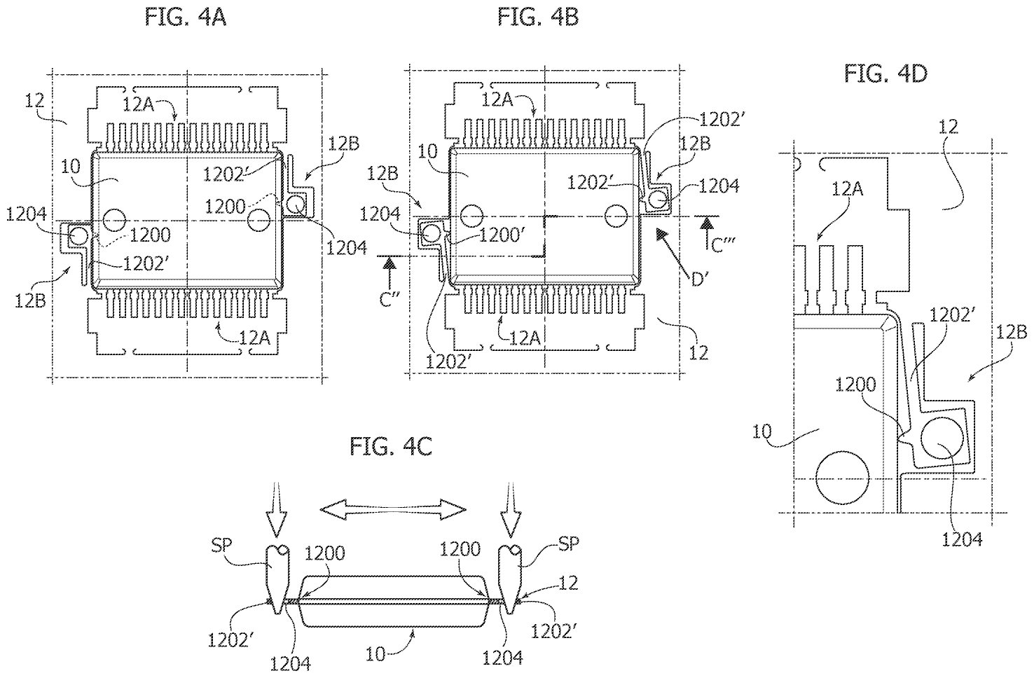

In FIGS. 3A to 3D and 4A to 4D parts or elements already discussed in connection with the previous figures are indicated with corresponding reference numerals and a detailed description will not be repeated for brevity.

FIGS. 3A to 3D and FIGS. 4A to 4D illustrate examples wherein the tie bars 12B have a deformable structure and include (sharp) pins 1200 configured to penetrate into the (plastic or resin) package of the devices 10 as illustrated in FIGS. 3A and 4A when a plurality of devices 10 are (still) connected in a chain during manufacturing.

As exemplified in the sequence of FIGS. 3A and 3B, and in the sequence of FIGS. 4A and 4B, the pins 1200 are configured to be withdrawn or extracted from the packages of the devices 10 so that these are released from the tie bars 12B. The devices 10 can thus be individually picked (as otherwise conventional in the art: see FIG. 1D, for instance) after being disengaged from the tie bars 12B as a result of the tie bars 12B being deformed.

FIGS. 3A to 3D and 4A to 4D are thus likewise exemplary of a process of producing a plurality of semiconductor devices 10 coupled in a chain extending in a longitudinal direction wherein neighboring devices 10 in the chain have mutually facing end sides transverse that longitudinal direction and are coupled via tie bars 12B located at the mutually facing transverse end sides.

In conventional solutions as illustrated in FIGS. 1A to 1D and 2A to 2E, releasing the individual devices 10 form the tie bars 12B involves severing or cutting the tie bars.

By way of contrast, the tie bars 12B of FIGS. 3A to 3D and 4A to 4D do not need to be severed or cut to release the individual devices 10 therebetween. As illustrated, the tie bars 12B of FIGS. 3A to 3D and 4A to 4D are provided with (pointed) anchoring tips 1200 configured to penetrate into mutually facing end sides of said devices 10. The tie bars 12B of FIGS. 3A to 3D and 4A to 4D are deformable to extract the anchoring tips (1200) from the mutually facing end sides of the devices 10. In that way, individual singulated devices 10 are produced in response to the anchoring tips 1200 being extracted from the mutually facing end sides of the devices 10.

Examples as discussed herein take advantage of the fact that plurality of semiconductor devices 10 manufactured simultaneously (as otherwise conventional in the art) can be coupled in a chain extending in a longitudinal direction and sharing a common substrate such a leadframe strip 12.

Deformable tie bars 12B as discussed herein can thus be provided as deformable portions 1202 of such a common substrate 12.

In a first possible embodiment as exemplified in FIGS. 3A to 3D, the pins 1200 can be carried by rectilinear struts 1202 formed in the leadframe 12 with each strut 1202 extending along (and facing) a respective end side of the package of a device 10. The struts 1202 can be configured as rectilinear portions of the leadframe 12 formed during production of the leadframe 12, for instance. This may occur in a manner known per se, via etching of metal material such as copper.

As illustrated, the struts 1202 may comprise (optionally at the side thereof facing away from the respective device end side) an engagement portion 1204. As illustrated, such an engagement portion includes a (through) hole 1204 formed in an extension of the strut 1202. As illustrated in FIG. 3C, the holes 1204 are adapted to be engaged by pins SP of a singulation tool.

As a result of penetrating into the holes 1204, the pins SP cause the struts 1202 (and the pointed pins 1200 carried thereby) to laterally move away from the package of device 10 into which the pins 1200 penetrate(d) to maintain the devices 10 coupled in a chain during the manufacturing steps prior to singulation.

In response to deformation of the struts 1202, the pins 1200 are extracted from the device packages, thus releasing the devices 10 from the tie bars 12B.

For instance, the pins SP can be arranged in a pair and be provided with conical distal tips. The conical tips of the pins in the pair have respective axes (of the conical tips) located a mutual distance that is larger than the distance between the axes of the holes 1204 provided in pair of tie bars 12B located at opposite sides of a same device 10 in the condition where the pins 1200 still penetrate in the semiconductor device packages (that is, with the tie bars 12B still undeformed).

As a result of the distance between the axes of the (conical tips of the) pins being slightly larger than the distance between the axes of the holes 1204—in the condition where the pins 1200 still penetrate the device packages—the advance movement of the pins SP into the holes 1204 (downwards in FIGS. 3C and 4C) causes the holes 1204 of the tie bars arranged on opposite sides of a same device 10 to laterally move away from each other and thus away of the device 10, thus causing the pins 1200 to disengage the device package.

This basic principle underlies both the implementation exemplified in FIGS. 3A to 3D and the implementation exemplified in FIGS. 4A to 4D.

Specifically, the arrows in FIGS. 3C and 4C are exemplary of the effect of the penetration of the pins SP in the holes 1204 of tie bars 12B located at opposite sides of the same semiconductor device 10 in laterally moving the holes (and the struts 1202 where these are formed) mutually away so that the pins 1200 disengage the semiconductor device 10 clamped therebetween.

That is, in examples as illustrated herein, engagement formations are provided in the form of holes 1024 formed in the tie bars 12B and a deformation tool SP of the tie bars 12B used for singulation comprises conical pins that are inserted off-center into these holes 1024 and advanced therein.

Advancing the conical pins SP into the holes 1024 (downwards as illustrated in FIGS. 3C and 4C) laterally moves the holes 1024 and the tie bars 12B having the holes 1204 provided therein away from the mutually facing end sides of the devices 10, which are thus singulated as desired.

It will be otherwise appreciated that a similar result can be obtained with a singulation tool including a pair of pins SP (not necessarily having a conical shape) that are inserted into the holes 1204 and then the pins are laterally moved away from each other as indicated by the double-pointed horizontal arrows shown in FIGS. 3C and 4C.

The implementation of FIGS. 3A to 3D contemplates using struts 1202 extending bridge-like between opposite (longitudinal) sides of the devices 10. Each strut 1202 thus forms a sort of beam member carrying, for instance, two pins 1200 at an intermediate portion thereof. Such beam members 1202 are thus deformable to move their intermediate portion away from the facing end sides of the devices 10. Inflection of the beam structure of the strut 1202 (as caused by the pins SP penetrating into the holes 1204, for instance) results into the pins 1200 being extracted from the package of the devices 10.

In the implementation illustrated in FIGS. 4A to 4D, the struts 1202 are in the form of cantilever structures carrying a pin 1200 at their distal end (where also the hole 1204 is provided). Here again, flexing of the cantilever structure of the struts 1202 (as caused by the pins SP penetrating into the holes 1204, for instance) results into the pins 1200 being extracted from the package of the device 10.

In the implementation illustrated in FIGS. 4A to 4D, the struts 1202 at opposite sides of a same device 10 are arranged at opposite ends of a notional diagonal line across the overall rectangular size of the device 10.

The implementation illustrated in FIGS. 4A to 4D thus comprises, for each semiconductor device 10: a first beam member 1202′ extending cantilever-like from one of the opposed longitudinal sides of the device 10 along a first end side of the device 10, and a second beam member 1202′ extending cantilever-like from the other of the opposed longitudinal sides of the device 10 along a second end side of the device 10.

Examples as illustrated herein take advantage of the possibility of forming the “operative” leads 12A in the leadframe strip 12 at the opposed longitudinal sides of the devices 10. This facilitates providing corresponding arrays of contact pins in the final package so that the two other “transversal” end sides of each device 10 can be left available for the provision of deformable tie bars 12B as discussed herein.

Examples as illustrated herein facilitate manufacturing semiconductor devices 10 where the transversal end sides are exempt from the presence of pins and, more to the point, from the presence of remainders of sacrificial (dummy) tie bars. This is beneficial in increasing the creepage distance.

Also, in so far as releasing the semiconductor devices 10 from the tie bars 12B does not involve severing the tie bars (as is the case of conventional solutions as depicted in FIGS. 1A to 1D and 2A to 2E) formation of cracks in the plastic or resin package of the devices 10 is avoided.

Individual semiconductor devices 10 can thus be produced comprising an (essentially rectangular of square) insulating package with a first pair of opposed longitudinal sides and a second pair of opposed end sides transverse the opposed longitudinal sides in the first pair.

Respective, electrically conductive contact pin arrays such as 12A can thus be left exposed at the first pair of opposed longitudinal sides while the second pair of opposed end sides comprise recesses punctured therein (where the pins 1200 initially penetrated into the device package). These end sides are thus exempt from electrically conductive formations.

Without prejudice to the underlying principles, the details and embodiments may vary, even significantly, with respect to what has been described in the foregoing, by way of example only, without departing from the extent of protection.

The claims are an integral part of the technical teaching on the embodiments as provided herein. The extent of protection is determined by the annexed claims.

1. A method, comprising:
producing a plurality of semiconductor devices coupled in a chain extending in a longitudinal direction, wherein neighboring devices in the chain have mutually facing end sides transverse to said longitudinal direction and are coupled via tie bars located at said mutually facing end sides;
providing the tie bars with anchoring tips penetrating into said mutually facing end sides of the devices in the chain;
providing the tie bars with engagement formations in the form of holes; and
inserting a deformation tool to engage with said holes and induce a lateral movement of said tie bars to extract the anchoring tips from the mutually facing end sides of the devices in the chain and produce individual singulated devices from said neighboring devices in the chain.

2. The method of claim 1, wherein:
the plurality of semiconductor devices coupled in said chain extend in a longitudinal direction share a common substrate; and
the tie bars comprise deformable portions of said common substrate.

3. The method of claim 1, wherein the tie bars comprise at least one strut extending along a respective one of said mutually facing end sides of said devices, the at least one strut carrying at least one anchoring tip configured to penetrate into said respective one of said mutually facing end sides of said devices, and wherein inserting to induce lateral movement causes a deformation of the at least one strut to extract the at least one anchoring tip from said respective one of said mutually facing end sides of said neighboring devices.

4. The method of claim 3, wherein the deformation tool comprises conical pins and wherein inserting comprises inserting the conical pins off-center into said holes and advancing the conical pins through said holes to induce the lateral movement.

5. The method of claim 3, wherein the deformation tool comprises pins, and wherein inserting comprises inserting the pins into said holes, and further comprising causing a lateral movement of the pins to induce the lateral movement.

6. The method of claim 3, wherein:
the plurality of semiconductor devices coupled in a chain comprise opposed longitudinal sides extending in said longitudinal direction; and
said at least one strut comprises a beam member extending bridge-like between opposed longitudinal sides along a respective one of said mutually facing end sides of said devices, the beam member carrying at least one anchoring tip at an intermediate portion thereof, and wherein said lateral movement causes said intermediate portion to move away from said respective one of said mutually facing end sides of said neighboring devices.

7. The method of claim 3, wherein:
the plurality of semiconductor devices coupled in a chain comprise opposed longitudinal sides extending in said longitudinal direction; and
said at least one strut comprises a beam member extending cantilever-like from one of the opposed longitudinal sides along said respective one of said mutually facing end sides of said devices, the cantilever-like beam member carrying at least one anchoring tip at a distal portion thereof, and wherein said lateral movement causes the cantilever-like beam member to move away from said respective one of said mutually facing end sides of said devices.

8. The method of claim 7, further comprising providing, for each of said semiconductor devices coupled in a chain:
a first beam member extending cantilever-like from one of the opposed longitudinal sides along a first end side of said each one of said semiconductor devices; and
a second beam member extending cantilever-like from the other of the opposed longitudinal sides along a second end side of said each one of said semiconductor devices.

9. The method of claim 8, further comprising providing the first beam member and the second beam member at diagonally opposed locations of said each one of said semiconductor devices.

10. The method of claim 1, wherein the deformation tool comprises conical pins and wherein inserting comprises inserting the conical pins off-center into said holes and advancing the conical pins through said holes to induce the lateral movement.

11. The method of claim 1, wherein the deformation tool comprises pins, and wherein inserting comprises inserting the pins into said holes, and further comprising causing a lateral movement of the pins to induce a lateral movement of said tie bars to extract the anchoring tips from the mutually facing end sides of the devices in the chain.

12. A leadframe strip comprising a chain of device locations extending in a longitudinal direction, wherein neighboring device locations in the chain have mutually facing end sides transverse to said longitudinal direction and are coupled via tie bars located at said mutually facing end sides, said leadframe strip further including tie bars with anchoring tips configured for penetrating into mutually facing end sides of device packages, wherein the tie bars include engagement formations in the form of holes, said holes configured to engage with a deformation tool causing a lateral movement of the tie bars for extraction of the anchoring tips from the mutually facing end sides of the device packages.

13. The leadframe strip of claim 12, wherein the tie bars comprise at least one strut extending along a respective one of said mutually facing end sides, the at least one strut carrying at least one anchoring tip.

14. The leadframe strip of claim 13, wherein said at least one strut comprises a beam member extending bridge-like between opposed longitudinal sides along a respective one of said mutually facing end sides, the beam member carrying at least one anchoring tip at an intermediate portion thereof.

15. The leadframe strip of claim 13, wherein said at least one strut comprises a beam member extending cantilever-like from one of the opposed longitudinal sides along said respective one of said mutually facing end sides, the cantilever-like beam member carrying at least one anchoring tip at a distal portion thereof.

16. The leadframe strip of claim 13, further comprising:
a first beam member extending cantilever-like from one of the opposed longitudinal sides along a first end side of said each one of said device locations; and
a second beam member extending cantilever-like from the other of the opposed longitudinal sides along a second end side of said each one of said device locations.

17. The leadframe strip of claim 16, wherein the first beam member and the second beam member are provided at diagonally opposed locations of said each one of said device locations.

18. A semiconductor device, comprising:
an insulating package with a first pair of opposed longitudinal sides and a second pair of opposed end sides transverse the opposed longitudinal sides in the first pair; and
respective, electrically conductive contact pin arrays exposed at said first pair of opposed longitudinal sides;
wherein the second pair of opposed end sides comprise recesses punctured therein and are exempt from electrically conductive formations exposed at said second pair of opposed end sides.
